(19) United States
(12) Patent Application Publication
(10) Pub. No.: US 2023/0037147 A1
(43) Pub. Date: Feb. 2, 2023

(54) HIGH-EFFICIENCY PHOTOELECTROCHEMICAL ELECTRODE AS HYDROGEN GENERATOR COMPOSED OF METAL OXIDE AND TRANSITION METAL DICHALCOGENIDE BOND ON THREE-DIMENSIONAL CARBON TEXTILE AND METHOD OF MANUFACTURING SAME

(71) Applicant: KOREA INSTITUTE OF SCIENCE AND TECHNOLOGY, Seoul (KR)

(72) Inventors: Dong Ick SON, Wanju-gun (KR); Dong Hee PARK, Seoul (KR); Joo Song LEE, Wanju-gun (KR)

(73) Assignee: KOREA INSTITUTE OF SCIENCE AND TECHNOLOGY, Seoul (KR)

(21) Appl. No.: 17/574,764

(22) Filed: Jan. 13, 2022

(30) Foreign Application Priority Data
Jul. 30, 2021 (KR) 10-2021-0100288
Jul. 30, 2021 (KR) 10-2021-0100292

(51) Int. Cl. C25B 11/052; H01B 1/02; C25B 11/091; C25B 11/056; C25B 1/55; C25B 11/065; C25B 1/04

(52) U.S. Cl. CPC C25B 11/052; H01B 1/02; C25B 11/091; C25B 11/056; C25B 1/55; C25B 11/065; C25B 1/04

(57) ABSTRACT

Disclosed are a photoelectrochemical electrode and a method of manufacturing the same, which enable mass production at low cost. The photoelectrochemical electrode manufactured by forming a transition metal dichalcogenide layer on all or part of the surface of a porous substrate includes a porous substrate and a metal dichalcogenide layer on all or part of the surface of the porous substrate, thus improving photoelectrode characteristics and photocatalytic efficiency.

### TECHNICAL FIELD

The present invention relates to a photoelectrochemical electrode having photoelectrode characteristics and improved hydrogen evolution efficiency due to water electrolysis, and a method of manufacturing the same.

### BACKGROUND ART

Thorough research is ongoing into the use of photoelectrochemistry technology in applications such as energy conversion and environmental purification. For example, artificial photosynthesis technology for synthesizing useful compounds from carbon dioxide (CO₂) and water (H₂O) using solar energy is under active study. According to artificial photosynthesis technology, it is possible to synthesize useful carbon compounds such as methane, methanol, formic acid and the like by making carbon dioxide, which is a representative greenhouse gas, react with water using solar energy. Specifically, since artificial photosynthesis technology enables conversion and storage of solar energy while reducing emission of greenhouse gas through carbon dioxide conversion, it is considered to be a method that is capable of simultaneously solving environmental problems and energy problems.

A photoelectrochemical reaction is carried out in a manner in which light energy is absorbed at the electrode surface to generate electrons and the generated electrons react with a feed (e.g. carbon dioxide) at a reactive site on the electrode surface. Since the efficiency of such a photoelectrochemical reaction is strongly dependent on the performance of the electrode, the development of a photoelectrochemical electrode capable of exhibiting high efficiency is required.

### DISCLOSURE

### Technical Problem

The present invention is intended to solve the above problems, and specific objects thereof are as follows.

An object of the present invention is to provide a method of manufacturing a photoelectrochemical electrode including forming a metal dichalcogenide layer on all or part of the surface of a porous substrate.

Another object of the present invention is to provide a photoelectrochemical electrode including a porous substrate and a metal dichalcogenide layer located on all or part of the porous surface, manufactured using the method described above.

The objects of the present invention are not limited to the foregoing. The objects of the present invention will be able to be clearly understood through the following description and to be realized by the means described in the claims and combinations thereof.

### Technical Solution

An embodiment of the present invention provides a method of manufacturing a photoelectrochemical electrode including preparing a porous substrate and forming a metal dichalcogenide layer on all or part of the surface of the porous substrate.

The method may further include performing carbonization by heat treatment at a temperature of 950° C. to 1050° C. for 30 minutes to 90 minutes, after preparing the porous substrate.

The forming the metal dichalcogenide layer may include preparing a growth solution including metal dichalcogenide particles, mixing and dispersing the growth solution and the porous substrate, and heating the result of dispersion at a temperature of 240° C. to 260° C. for 4 hours to 6 hours.

The method may further include forming a metal oxide layer on all or part of the surface of the porous substrate.

The forming the metal oxide layer may include coating the porous substrate with metal oxide nanoparticles using a sputtering system.

The forming the metal oxide layer may be performed at a pressure of 0.5 mTorr or more in an atmosphere containing an inert gas.

In addition, an embodiment of the present invention provides a photoelectrochemical electrode including a porous substrate and a metal dichalcogenide layer located on all or part of the surface of the porous substrate.

The porous substrate may be a carbon fiber textile (C-fiber textile).

The metal dichalcogenide layer may have a flower or sea urchin shape in which metal dichalcogenide particles are aggregated, and a thin-film shape.

The metal dichalcogenide particles may include a metal including at least one selected from among molybdenum (Mo), tungsten (W), tin (Sn), niobium (Nb), tantalum (Ta), hafnium (Hf), titanium (Ti), and rhenium (Re), and a chalcogen element including at least one selected from among sulfur (S), selenium (Se), and tellurium (Te).

The photoelectrochemical electrode may further include a metal oxide layer located on all or part of the surface of the porous substrate.

The metal oxide nanoparticles included in the metal oxide layer may include at least one selected from the group consisting of titanium (Ti) oxide, tin (Sn) oxide, indium (In) oxide, magnesium (Mg) oxide, magnesium zinc (MgZn) oxide, indium zinc (InZn) oxide, copper aluminum (CuAl) oxide, silver (Ag) oxide, gallium (Ga) oxide, zinc tin oxide (ZnSnO), zinc indium tin (ZIS) oxide, nickel (Ni) oxide, rhodium (Rh) oxide, ruthenium (Ru) oxide, iridium (Ir) oxide, copper (Cu) oxide, cobalt (Co) oxide, tungsten (W) oxide, zirconium (Zr) oxide, strontium (Sr) oxide, lanthanum (La) oxide, vanadium (V) oxide, molybdenum (Mo) oxide, niobium (Nb) oxide, aluminum (Al) oxide, yttrium (Y) oxide, scandium (Sc) oxide, samarium (Sm) oxide, strontium titanium (SrTi) oxide, and vanadium oxide (V).

The thickness of the metal oxide layer may be 300 nm to 1 μm.

### Advantageous Effects

According to the present invention, a method of manufacturing a photoelectrochemical electrode enables mass production at low cost. Meanwhile, a photoelectrochemical electrode manufactured using the same is configured such that a transition metal dichalcogenide layer synthesized on a porous substrate has a maximized surface area, so the distance-dependent difference in potential inside the electrode is constant and high efficiency thereof can thus be maintained, thus exhibiting high reactivity and reliable performance reproducibility compared to a film-like structure, thereby improving photoelectrode characteristics and water electrolysis efficiency.

In addition, in the method of manufacturing the photoelectrochemical electrode according to the present invention, since metal oxide is deposited at room temperature, rather than a high temperature, cracks and defects due to the coefficient of thermal expansion do not occur, and moreover, the transition metal dichalcogenide layer grown through hydrothermal synthesis has the advantage of increasing electron transport efficiency and photocatalytic efficiency by densely coating and bonding the metal oxide layer, whereby the photoelectrochemical electrode thus manufactured has high reactivity compared to the film-type structure due to the metal oxide layer and the transition metal dichalcogenide layer having a maximized surface area synthesized on the porous substrate and the bonding energy therebetween, ultimately improving photoelectrode characteristics and photocatalytic efficiency.

The effects of the present invention are not limited to the foregoing. The effects of the present invention should be understood to include all effects that may be reasonably anticipated from the following description.

### DESCRIPTION OF DRAWINGS

FIG. 1 is an enlarged view of the internal structure of a photoelectrochemical electrode;

FIGS. 2A to 2C are an SEM image of the photoelectrochemical electrode of Example 1 (FIG. 2A), an SEM image of the photoelectrochemical electrode of Example 2 (FIG. 2B), and an SEM image of the photoelectrochemical electrode of Example 3 (FIG. 2C), respectively;

FIGS. 3A to 3C are graphs showing the hydrogen evolution results of the photoelectrochemical electrodes according to Example 1 (FIG. 3A), Example 2 (FIG. 3B), and Example 3 (FIG. 3C), respectively;

FIG. 4 is a graph showing the current density results for the photoelectrochemical electrode according to Example 1 when irradiated with light at 1 sun and in the dark;

FIG. 5 is a graph showing the current density results for the photoelectrochemical electrode according to Example 2 when irradiated with light at 1 sun and in the dark;

FIG. 6 is a graph showing the current density results for the photoelectrochemical electrode according to Example 3 when irradiated with light at 1 sun and in the dark;

FIG. 7 is a graph showing the current density results for the photoelectrochemical electrodes according to Comparative Examples 1 and 2;

FIG. 8 is an enlarged view of the internal structure of a photoelectrochemical electrode;

FIGS. 9A to 9C are an SEM image of a carbonized C-fiber textile, which is a porous substrate (FIG. 9A), an SEM image of the photoelectrochemical electrode according to Comparative Example 3 (FIG. 9B), and an SEM image of the photoelectrochemical electrode according to Example 4 (FIG. 9C), respectively;

FIG. 10 is a low-magnification SEM image of the photoelectrochemical electrode according to Example 4;

FIG. 11A is a TEM image showing the interface between the metal oxide layer and the transition metal dichalcogenide layer in the photoelectrochemical electrode, and FIG. 11B is a TEM image showing the interface between the porous substrate and the metal oxide layer in the photoelectrochemical electrode;

FIG. 12 is a STEM image showing the interface between the metal oxide layer and the transition metal dichalcogenide layer;

FIGS. 13A to 13D are, respectively, an image mapped to the Ti element (FIG. 13A), an image mapped to the O element (FIG. 13B), an image mapped to the Mo element (FIG. 13C), and an image mapped to the S element (FIG. 13D), based on EDX elemental analysis in FIG. 13;

FIGS. 14A to 14C are graphs showing the current density results for the photoelectrochemical electrodes according to Example 4 (FIG. 14A), Comparative Example 3 (FIG. 14B), and Comparative Example 4 (FIG. 14C), respectively;

FIGS. 15A and 15B are graphs showing the hydrogen evolution results of the photoelectrochemical electrodes according to Example 4 (FIG. 15A) and Comparative Example 3 (FIG. 15B), respectively; and

FIG. 16 is a graph showing the photocatalytic efficiency of the photoelectrochemical electrode according to Example 4.

### BEST MODE

The above and other objects, features and advantages of the present invention will be more clearly understood from the following preferred embodiments taken in conjunction with the accompanying drawings. However, the present invention is not limited to the embodiments disclosed herein, and may be modified into different forms. These embodiments are provided to thoroughly explain the disclosure and to sufficiently transfer the spirit of the present invention to those skilled in the art.

Throughout the drawings, the same reference numerals will refer to the same or like elements. For the sake of clarity of the present invention, the dimensions of structures are depicted as being larger than the actual sizes thereof. It will be understood that, although terms such as “first”, “second”, etc. may be used herein to describe various elements, these elements are not to be limited by these terms. These terms are only used to distinguish one element from another element. For instance, a “first” element discussed below could be termed a “second” element without departing from the scope of the present invention. Similarly, the “second” element could also be termed a “first” element. As used herein, the singular forms are intended to include the plural forms as well, unless the context clearly indicates otherwise.

It will be further understood that the terms “comprise”, “include”, “have”, etc., when used in this specification, specify the presence of stated features, integers, steps, operations, elements, components, or combinations thereof, but do not preclude the presence or addition of one or more other features, integers, steps, operations, elements, components, or combinations thereof. Also, it will be understood that when an element such as a layer, film, area, or sheet is referred to as being “on” another element, it may be directly on the other element, or intervening elements may be present therebetween. Similarly, when an element such as a layer, film, area, or sheet is referred to as being “under” another element, it may be directly under the other element, or intervening elements may be present therebetween.

Unless otherwise specified, all numbers, values, and/or representations that express the amounts of components, reaction conditions, polymer compositions, and mixtures used herein are to be taken as approximations including various uncertainties affecting measurement that inherently occur in obtaining these values, among others, and thus should be understood to be modified by the term “about” in all cases. Furthermore, when a numerical range is disclosed in this specification, the range is continuous, and includes all values from the minimum value of said range to the maximum value thereof, unless otherwise indicated. Moreover, when such a range pertains to integer values, all integers including the minimum value to the maximum value are included, unless otherwise indicated.

In the present specification, when a range is described for a variable, it will be understood that the variable includes all values within the stated range, including the end points. For example, the range of “5 to 10” will be understood to include any subranges, such as 6 to 10, 7 to 10, 6 to 9, 7 to 9 and the like, as well as individual values of 5, 6, 7, 8, 9 and 10, and will also be understood to include any value between valid integers within the stated range, such as 5.5, 6.5, 7.5, 5.5 to 8.5, 6.5 to 9, and the like. Also, for example, the range of “10% to 30%” will be understood to include subranges, such as 10% to 15%, 12% to 18%, 20% to 30%, etc., as well as all integers including values of 10%, 11%, 12%, 13% and the like up to 30%, and will also be understood to include any value between valid integers within the stated range, such as 10.5%, 15.5%, 25.5%, and the like.

Since the efficiency of the photoelectrochemical reaction greatly depends on the performance of the electrode, the development of a photoelectrochemical electrode capable of exhibiting high efficiency is required.

Accordingly, the present inventors have endeavored to solve the above problems and thus ascertained that, when manufacturing a photoelectrochemical electrode through a method including forming a metal dichalcogenide layer on all or part of the surface of a porous substrate, photoelectrode characteristics and photocatalytic efficiency may be improved in the photoelectrochemical electrode including the porous substrate and the metal dichalcogenide layer located on all or part of the surface of the porous substrate, thus culminating in the present invention.

According to the present invention, the method of manufacturing a photoelectrochemical electrode includes preparing a porous substrate (S10) and forming a metal dichalcogenide layer on all or part of the surface of the porous substrate (S20).

The preparing the porous substrate (S10) is a step of preparing a substrate having high porosity in order to increase the surface area of the photoelectrochemical electrode to be manufactured later.

The porous substrate may be a substrate that is typically used for a photoelectrochemical electrode, and may include a transparent conductive oxide (TCO).

The porous substrate may include at least one selected from the group consisting of a transparent conductive oxide (TCO), for example, FTO (F-doped SnO₂: SnO₂:F), ITO, carbon compound, metal nitride, metal oxide, and a conductive polymer. Preferably, the porous substrate includes a carbon compound imparted with increased conductivity by carbonizing Oxi-PAN (oxidized polyacrylonitrile), which is inexpensive and mass-produced through recycling from polymer waste such as plastics, in order to perform a large-area process suitable for initial investment cost and high-efficiency energy conversion, and more preferably, the porous substrate is a carbon fiber textile (C-fiber textile) having high porosity of at least 30 or 40 count, which is finer and thinner than 20-count spun yarn, as the carbon compound.

Therefore, the porous substrate according to the present invention has high porosity and is thus capable of improving photoelectrochemical electrode characteristics and photocatalytic efficiency by enlarging the surface area for forming a metal oxide layer and a metal dichalcogenide layer later.

The C-fiber textile may be manufactured by preparing multiple carbon fiber strands, spinning 15 to 25 carbon fiber strands thereamong to afford spun carbon fiber yarn (spun C-fiber yarn), and weaving the spun C-fiber yarn.

The porous substrate thus prepared may be further subjected to a carbonization process by applying heat to the C-fiber textile to impart crystallinity to the amorphous carbon structure in the textile in order to improve the conductivity of the carbon fiber.

Specifically, the carbonization process may be performed by heat-treating the prepared porous substrate in a furnace at a temperature of 950° C. to 1050° C. for 30 minutes to 90 minutes in an inert gas atmosphere, preferably at a temperature of 1000° C. for 60 minutes in a nitrogen atmosphere as the inert gas atmosphere, followed by cooling to room temperature at a cooling rate of −5° C./hour to −80° C./hour. Outside of the above ranges, if the temperature of the carbonization process is too low, the amorphous structure of the carbon fiber may not change to a crystalline structure, so conductivity may not be improved, whereas if the temperature thereof is too high, the amorphous carbon structure may be decomposed and damaged. In addition, if the time of the carbonization process is too short, the crystallinity of the carbon fiber may not be sufficient, whereas if the time thereof is too long, production efficiency may be decreased. In addition, if the cooling rate is too slow, production efficiency may be decreased, whereas if the cooling rate is too fast, the mechanical properties of the fiber may be deteriorated due to a rapid temperature change.

Also, the method of manufacturing the photoelectrochemical electrode may further include forming a metal oxide layer after preparing the porous substrate and before forming the metal dichalcogenide layer.

Specifically, the forming the metal oxide layer is a step of imparting or improving photoelectrode characteristics or photocatalytic efficiency by forming the metal oxide layer on all or part of the surface of the prepared porous substrate.

The forming the metal oxide layer on the surface of the porous substrate may be conducted by performing coating with metal oxide nanoparticles using a sputtering system. When the metal oxide layer is formed using the sputtering system, there is an advantage in that a metal oxide layer having high crystallinity may be easily and inexpensively formed through coating at room temperature.

Here, the metal oxide nanoparticles may include at least one selected from the group consisting of titanium (Ti) oxide, tin (Sn) oxide, indium (In) oxide, magnesium (Mg) oxide, magnesium zinc (MgZn) oxide, indium zinc (InZn) oxide, copper aluminum (CuAl) Oxide, silver (Ag) oxide, gallium (Ga) oxide, zinc tin oxide (ZnSnO), zinc indium tin (ZIS) oxide, nickel (Ni) oxide, rhodium (Rh) oxide, ruthenium (Ru) oxide, iridium (Ir) oxide, copper (Cu) oxide, cobalt (Co) oxide, tungsten (W) oxide, zirconium (Zr) oxide, strontium (Sr) oxide, lanthanum (La) oxide, vanadium (V) oxide, molybdenum (Mo) oxide, niobium (Nb) oxide, aluminum (Al) oxide, yttrium (Y) oxide, scandium (Sc) oxide, samarium (Sm) oxide, strontium titanium (SrTi) oxide, and vanadium oxide (V). Preferably, titanium dioxide (TiO₂) is used as titanium (Ti) oxide, which may be synthesized into a metal oxide layer at room temperature and is able to improve the photocatalytic efficiency due to bonding energy through bonding with a transition metal dichalcogenide layer to be formed later, unlike other types.

As necessary, a metal nitride layer, a metal sulfide layer, or a metal carbide layer may be formed, rather than the metal oxide layer.

The sputtering system is capable of performing a process of coating with the prepared metal oxide nanoparticles to a thickness of 10 nm or more at a pressure of 0.5 mTorr or more in an inert gas atmosphere in a sputtering machine maintained in a vacuum state, and preferably, the metal oxide layer is formed on the porous substrate by generating a sputtering plasma by applying a power of 1 W or more per unit cm² area to the metal oxide nanoparticle target at a pressure of 0.5 mTorr to 10 mTorr in a gas atmosphere in which argon gas, which is an inert gas, and oxygen gas, which is a reactive gas, are placed in a sputtering machine maintained in a vacuum state.

The forming the metal dichalcogenide layer (S20) is a step of forming a metal dichalcogenide layer, which is a photosensitive layer, on all or part of the surface of the porous substrate or on all or part of the surface of the result of formation of the metal oxide layer.

The photosensitive material included in the photosensitive layer serves as an active material layer that causes movement of electrons and holes due to photoreaction in the electrolyte, and thus exhibits vastly superior effects than a photosensitive layer made of a pure material. The photosensitive material that may be used in the photosensitive layer may include at least one selected from the group consisting of quantum dots, porphyrin dyes having Q bands in the wavelength range of 500 to 600 nm, corresponding to the visible light range, squaraine dyes, and ruthenium-based dyes.

The ruthenium-based dye may be a photosensitive dye because it has an MLCT (metal to ligand charge transfer) band and thus high absorbance in the UV wavelength range of about 530 to 610 nm, and preferably includes at least one selected from the group consisting of N719, N3, Ru505, and Z907.

In particular, the quantum dots have a band gap of 1.55 eV to 3.1 eV and are capable of absorbing visible light, and preferably, the metal dichalcogenide particles include a metal including at least one selected from among molybdenum (Mo), tungsten (W), tin (Sn), niobium (Nb), tantalum (Ta), hafnium (Hf), titanium (Ti), cadmium (Cd), lead (Pb), and rhenium (Re), and a chalcogen element including at least one selected from among sulfur (S), selenium (Se), and tellurium (Te). For example, at least one selected from among MoS₂, CdS, CdSe, CdTe, PbS, PbSe, and complexes thereof may be used, and more preferably used is MoS₂, which has high charge mobility compared to other materials, is capable of being synthesized in large amounts, and is capable of improving photocatalytic efficiency by forming a flower or sea urchin shape and a thin-film shape.

The forming the metal dichalcogenide layer using the metal dichalcogenide particles as the photosensitive material may be performed using a hydrothermal synthesis method. When the metal dichalcogenide layer is formed through the hydrothermal synthesis method, the porous substrate is coated with a small amount of metal dichalcogenide precursor in a flower shape, which maximizes the surface area, and in a thin-film shape, thus forming a core-shell structure, which is advantageous in that the charge is transferred through the metal dichalcogenide layer, which is the active layer, rather than the electrolyte coming into direct contact with the porous substrate, thereby increasing the intrinsic efficiency thereof.

The hydrothermal synthesis method is a kind of liquid-phase synthesis method, and pertains to a process for synthesizing a material using water or a thermal solution or fluid at a high temperature under high pressure, and is particularly a method of synthesizing single crystals, which depends on solubility using hot water under high pressure.

The forming the metal dichalcogenide layer using the hydrothermal synthesis method according to the present invention includes preparing a growth solution including a metal dichalcogenide particle precursor (S21), mixing and dispersing the growth solution and the porous substrate (S22), and heating the result of dispersion at a temperature of 240° C. to 260° C. for 4 hours to 6 hours (S23).

The preparing the growth solution (S21) is a step of preparing a growth solution to be later grown on the surface of the porous substrate by including the metal dichalcogenide particle precursor.

Specifically, the dichalcogenide particle precursor may be configured such that at least one selected from the group consisting of ammonium ions, sodium ions, and sulfur ions is joined to dichalcogenide particles.

The growth solution may be prepared by adding the dichalcogenide particle precursor to a solvent. The solvent that is used may include at least one selected from the group consisting of diethylformamide (DMF) and oleylamine.

The dispersion step (S22) is a step of mixing and dispersing the prepared growth solution and the porous substrate.

The dispersion may be carried out through an ultrasonic method, and preferably, the growth solution and the result of formation of the metal oxide layer are ultrasonically dispersed for 8 minutes to 12 minutes. Outside of the above range, if the dispersion time is too short, the dichalcogenide particle precursor and oleylamine, which is an additive, may not be mixed well, making it difficult to realize uniform growth, whereas if the dispersion time is too long, production efficiency may be decreased.

The heating step (S23) is a step of finally forming a metal dichalcogenide layer on all or part of the surface of the porous substrate by heating the result of dispersion.

Specifically, in the heating step, the result of dispersion may be heated at a temperature of 240° C. to 260° C. for 4 hours to 6 hours. Outside of the above ranges, if the heating temperature is too low, the dichalcogenide may not be synthesized and may remain in the form of MoO₃ before growth, whereas if the heating temperature is too high, the dichalcogenide may be thermally decomposed. In addition, if the heating time is too short, the dichalcogenide precursor may not be sufficiently synthesized into dichalcogenide, whereas if the heating time is too long, production efficiency may be lowered.

The method of manufacturing the photoelectrochemical electrode according to the present invention advantageously enables mass production at low cost.

FIG. 1 is an enlarged view of the internal structure of a photoelectrochemical electrode.

With reference to FIG. 1, the photoelectrochemical electrode according to the present invention includes a porous substrate and a metal dichalcogenide layer located on all or part of the surface of the porous substrate.

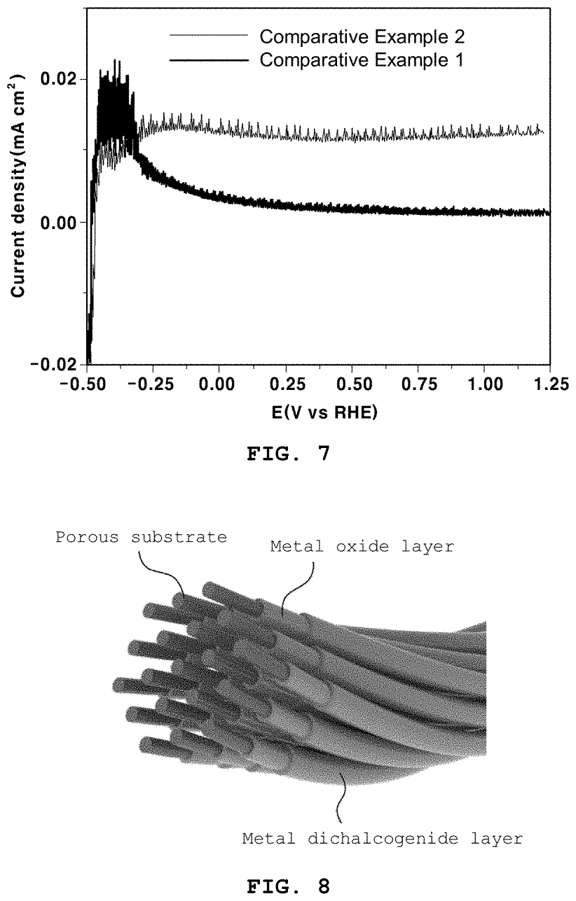

Also, FIG. 8 is an enlarged view of the internal structure of another photoelectrochemical electrode.

With reference to FIG. 8, the photoelectrochemical electrode according to the present invention includes a porous substrate, a metal oxide layer located on all or part of the surface of the porous substrate, and a transition metal dichalcogenide layer located on all or part of the surface of the metal oxide layer. Content redundant with the method of manufacturing the photoelectrochemical electrode will be omitted, and configurations will be described.

The porous substrate may be a C-fiber textile, and the porous substrate may have a porosity of 80% to 95% based on a total volume of 100%. Outside of the above range, if the porosity is too low, efficiency may be decreased due to the narrowed surface area ratio.

The metal oxide layer located on all or part of the surface of the porous substrate is a layer serving as a photocatalyst, and the thickness of the metal oxide layer may be 300 nm to 1 μm. Outside of the above range, if the thickness of the metal oxide layer is too low, the layer that absorbs light may be reduced and thus decreased efficiency may result, whereas if the thickness thereof is too high, the transmittance of the material may be decreased and photocatalytic efficiency may be lowered.

Moreover, the metal dichalcogenide layer, which may be located on all or part of the surface of the porous substrate or on all or part of the surface of the metal oxide layer includes a photosensitive material and thus serves as an active material layer that causes movement of electrons and holes due to photoreaction in the electrolyte, and may have a flower or sea urchin shape in which metal dichalcogenide particles are aggregated. The metal dichalcogenide layer has a flower or sea urchin shape in which metal dichalcogenide particles are aggregated, so it has a porous structure and enables a photocatalytic reaction over a large surface area, and furthermore, there is a structural advantage of preventing efficiency from being lowered due to direct contact of the electrolyte with the porous substrate owing to a form that completely surrounds the porous substrate, which is an inner layer.

The photoelectrochemical electrode according to the present invention that satisfies the foregoing is capable of improving photoelectrode characteristics and photocatalytic efficiency.

### MODE FOR INVENTION

A better understanding of the present invention may be obtained through the following examples. These examples are merely set forth to illustrate the present invention and are not to be construed as limiting the scope of the present invention.

### Example 1: Manufacture of Photoelectrochemical Electrode

A porous substrate was prepared as follows.

Specifically, carbon fiber, namely Oxi-PAN (oxidized polyacrylonitrile) was prepared. 20 carbon fiber strands were prepared and manufactured into spun C-fiber yarn through a spinning process, after which the spun C-fiber yarn was woven to afford a C-fiber textile having a porosity of 80 to 95%. Then, the C-fiber textile as the porous substrate prepared above was placed in the center of an alumina (Al₂O₃) tube, heat-treated at 1100° C. for 2 hours in a furnace with argon gas at a flow rate of 300 sccm, and then cooled to room temperature (25° C.) at a cooling rate of −5° C./hour.

A metal dichalcogenide layer was formed on the surface of the result of formation of the porous substrate through the following method.

Specifically, 100 mg of ammonium tetrathiomolybdate ((NH₄)₂MoS₄) as a dichalcogenide particle precursor was mixed with 50 ml of a solvent mixture of dimethylformamide (DMF) and oleylamine at a ratio of 1:1 to afford a growth solution. Then, the porous substrate and the growth solution were ultrasonically dispersed for 10 minutes. The result of dispersion was placed in a hydrothermal autoclave and sealed, the hydrothermal autoclave was placed in a vacuum oven, and the inside of the oven was evacuated to prevent solvent leakage. Then, the oven was heated at 250° C. for 5 hours, thereby forming a dichalcogenide layer on the surface of the porous substrate.

### Examples 2 and 3: Manufacture of Photoelectrochemical Electrode

Respective photoelectrochemical electrodes were manufactured in the same manner as in Example 1, with the exceptions that:

a photoelectrochemical electrode including a dichalcogenide layer on a carbon textile was manufactured using 150 mg of ammonium tetrathiomolybdate ((NH)₂MoS₄) as the dichalcogenide particle precursor (Example 2), and

a photoelectrochemical electrode including a dichalcogenide layer on a carbon textile was manufactured using 200 mg of ammonium tetrathiomolybdate ((NH)₂MoS₄) as the dichalcogenide particle precursor (Example 3), unlike Example 1.

### Example 4: Manufacture of Photoelectrochemical Electrode Including Metal Oxide Layer

A porous substrate was prepared as follows.

Specifically, carbon fiber, namely Oxi-PAN (oxidized polyacrylonitrile) was prepared. 20 carbon fiber strands were prepared and manufactured into spun C-fiber yarn through a spinning process, after which the spun C-fiber yarn was woven to afford a C-fiber textile having a porosity of 80 to 95%. Then, the C-fiber textile as the porous substrate prepared above was placed in the center of an alumina (Al₂O₃) tube, heat-treated at 1100° C. for 2 hours in a furnace with argon gas at a flow rate of 300 sccm, and then cooled to room temperature (25° C.) at a cooling rate of −5° C./hour.

A metal oxide layer was formed on the carbonized C-fiber textile as the porous substrate at room temperature using an in-line sputtering system having a width of 300 mm. Specifically, a vacuum of 4.5×10⁻⁶ Torr was established in a sputtering machine, after which 100 sccm of 5 N argon gas as inert gas and 10 sccm of oxygen gas were introduced into the machine and a pressure of 3.5 mTorr was maintained. Then, pulsed power of 1.5 kW was applied to 4 N metal oxide nanoparticles TiO₂ as a target for 60 minutes to generate a sputtering plasma, so the surface of the porous substrate was coated with a layer containing TiO₂ as a metal oxide layer, thereby manufacturing a result of formation of the metal oxide layer having a thickness of 1 μm.

A transition metal dichalcogenide layer was formed on the surface of the result of formation of the metal oxide layer through the following method.

Specifically, 100 mg of ammonium tetrathiomolybdate ((NH₄)₂MoS₄) as a dichalcogenide particle precursor was mixed with 25 ml of a solvent mixture of dimethylformamide (DMF) and oleylamine at a ratio of 1:1 to afford a growth solution. Then, the result of formation of the metal oxide layer and the growth solution were ultrasonically dispersed for 10 minutes. The result of dispersion was placed in a hydrothermal autoclave and sealed, the hydrothermal autoclave was placed in a vacuum oven, and the inside of the oven was evacuated to prevent solvent leakage. Then, the oven was heated at 250° C. for 5 hours, so the dichalcogenide particle precursor was formed in a flower or sea urchin shape in which MoS₂, which is dichalcogenide particles, was aggregated, thereby forming a dichalcogenide layer on the surface of the result of formation of the metal oxide layer.

### Comparative Example 1: Photoelectrochemical Electrode Including Dichalcogenide Layer Formed on Film Substrate

A photoelectrochemical electrode was manufactured in the same manner as in Example 1, with the exception that an FTO-based film-type substrate was used, rather than the porous substrate at (S10) as in Example 1.

### Comparative Example 2: Photoelectrochemical Electrode Including Dichalcogenide Layer Formed on Film Substrate

A photoelectrochemical electrode was manufactured in the same manner as in Comparative Example 1, with the exception that the photoelectrochemical electrode was manufactured using 200 mg of ammonium tetrathiomolybdate ((NH₄)₂MoS₄) as the dichalcogenide particle precursor, unlike Comparative Example 1.

### Comparative Example 3: Manufacture of Photoelectrochemical Electrode Excluding Transition Metal Dichalcogenide Layer

A photoelectrochemical electrode was manufactured in the same manner as in Example 4, with the exception that the step of forming a dichalcogenide layer was not performed, unlike Example 4.

### Comparative Example 4: Manufacture of Photoelectrochemical Electrode Using FTO/Glass Substrate

A photoelectrochemical electrode was manufactured in the same manner as in Example 4, with the exception that an FTO/glass substrate was used, rather than the porous substrate as in Example 4.

### Test Example 1: Analysis of Photoelectrochemical Electrode

The surfaces of the photoelectrochemical electrodes according to Examples 1 to 3 were observed, and the results thereof are shown as SEM images.

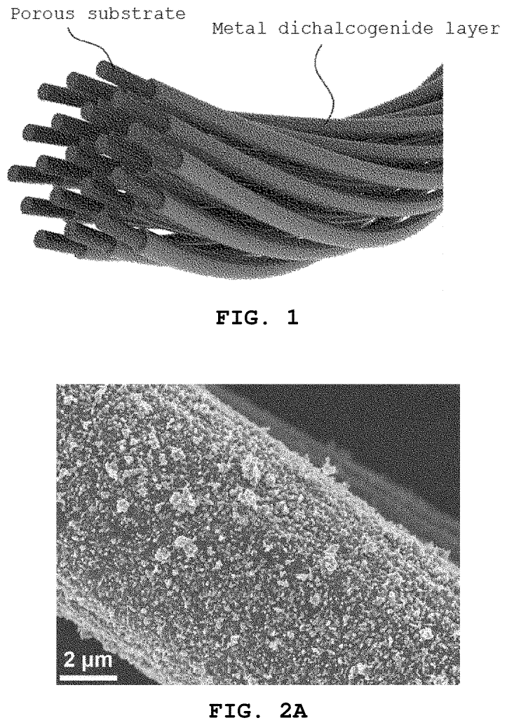

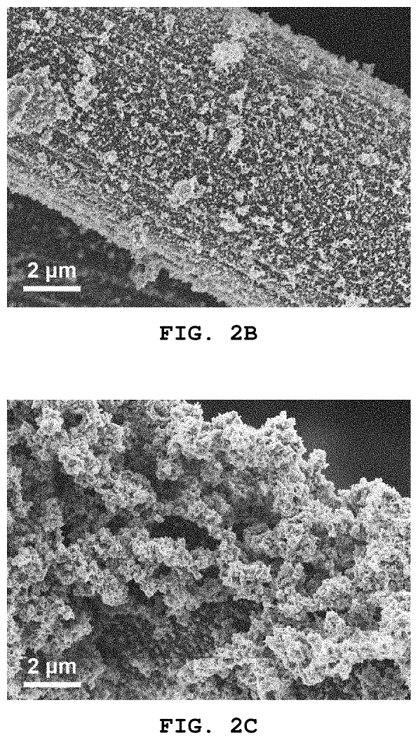

Specifically, FIGS. 2A to 2C are an SEM image of the photoelectrochemical electrode of Example 1 (FIG. 2A), an SEM image of the photoelectrochemical electrode of Example 2 (FIG. 2B), and an SEM image of the photoelectrochemical electrode of Example 3 (FIG. 2C), respectively.

With reference to FIGS. 2A to 2C, it was confirmed that a metal dichalcogenide layer having a flower shape in which the metal dichalcogenide particles were aggregated was formed on the surface of the C-fiber textile, and also that the scale of the metal dichalcogenide layer was increased with an increase in the mass of the metal dichalcogenide particles.

### Test Example 2: Analysis of Electrical Properties of Photoelectrochemical Electrode

The current density and hydrogen evolution of the photoelectrochemical electrodes according to Examples 1 to 3 were measured through the following tests. Specifically, in order to confirm a PEC reaction using the reference electrode Ag/AgCl (NaCl 3M) and the counter Pt electrode in a 0.5 M Na₂SO₄ aqueous solution, the current density was analyzed in the voltage range of 0 V to 1.25 V (E vs. RHE). In addition, hydrogen evolution was analyzed by setting a fixed voltage of 1.23 V (E vs. RHE) and measuring the amount of dissolved hydrogen (μmol/L) over time using a hydrogen sensor. The results thereof are shown in a current density graph and a hydrogen evolution graph.

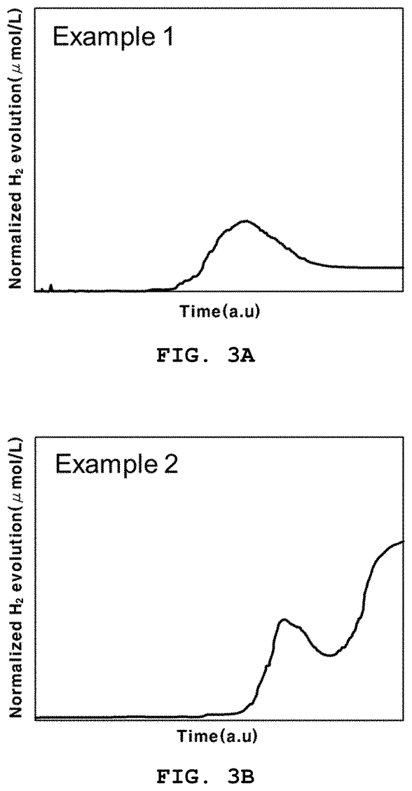

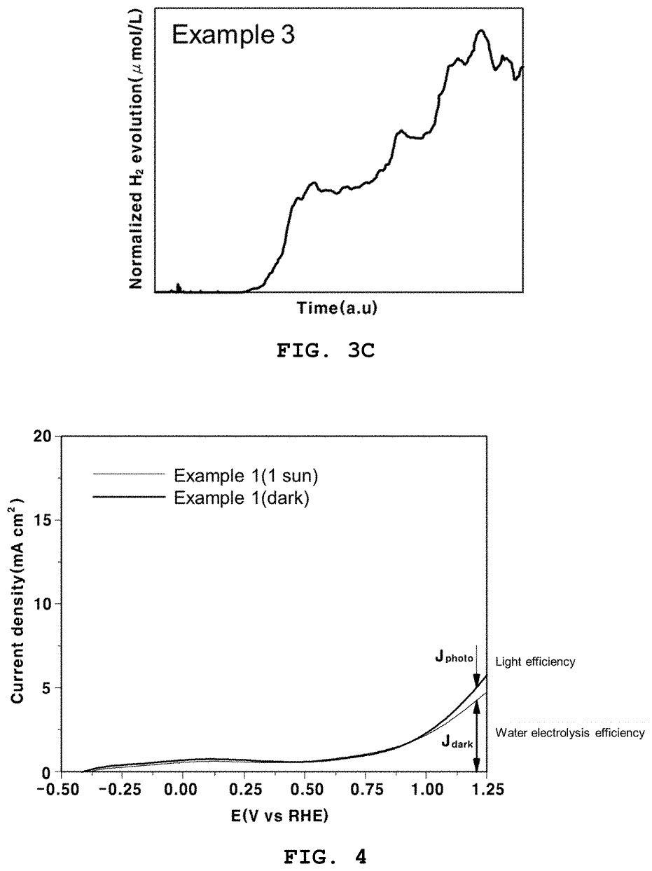

Specifically, FIGS. 3A to 3C are graphs showing the hydrogen evolution results of the photoelectrochemical electrodes according to Example 1 (FIG. 3A), Example 2 (FIG. 3B), and Example 3 (FIG. 3C), respectively. FIG. 4 is a graph showing the current density results for the photoelectrochemical electrodes according to Examples 1 to 3.

The current density graph showed that the larger the on/off gap, the more light the photosensitive material absorbs, thereby generating higher current density, indicating high-efficiency photoelectrochemical properties. With reference to FIG. 4, it was found that the current density of the photoelectrochemical electrodes according to Examples 1 to 3 was increased with an increase in the mass of the metal dichalcogenide particles.

With reference to FIGS. 3A to 3C, it was found that the hydrogen evolution rate increased in proportion to the increase in current density.

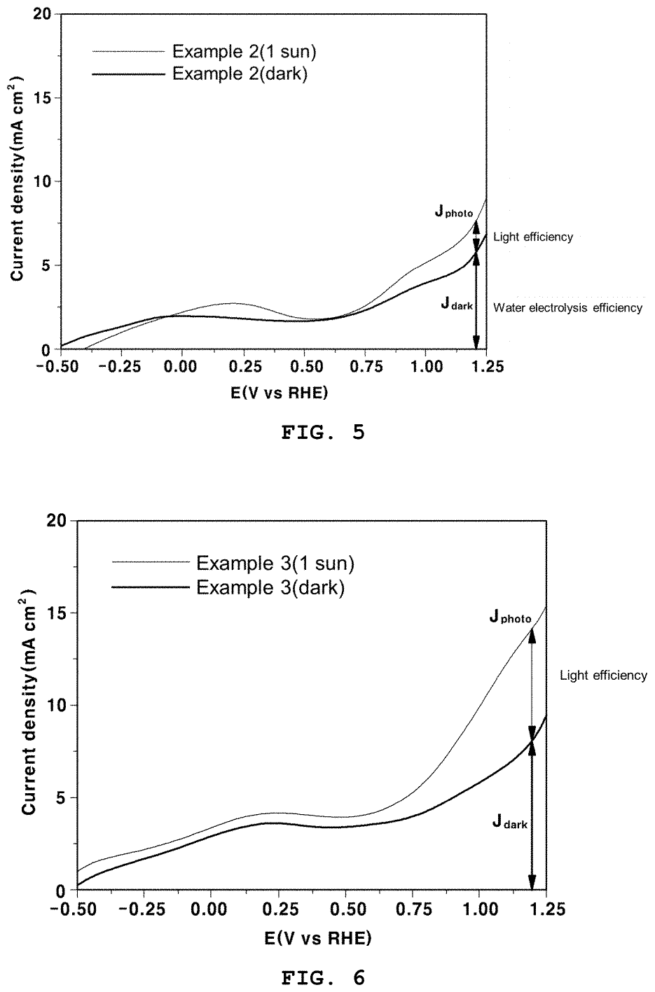

With reference to FIGS. 4 to 6, it can be confirmed that current density is improved with an increase in the amount of the dichalcogenide particle precursor. In particular, when the photoelectrochemical electrode was irradiated with light at 1 sun (intensity of light similar to sunlight=1 sun (fixed value) during photoelectrochemical measurement), the dichalcogenide particles in the metal dichalcogenide layer received light and generated current (light efficiency). Here, the current density was increased with an increase in the amount of the precursor. In addition, whether the dichalcogenide particles in the metal dichalcogenide layer generate current other than light-based current in a dark state was evaluated, and the results indicated that water electrolysis efficiency, which is a water decomposition reaction due only to current density without a light reaction, as the current density generated by the voltage, was also increased with an increase in the amount of the precursor.

Moreover, with reference to FIGS. 4 and 7 and FIGS. 6 and 7, even when the dichalcogenide particle precursor was used in the same amount, the current density of the photoelectrochemical electrodes according to Example 1 and Example 3 was greater than the current density of the photoelectrochemical electrodes according to Comparative Example 1 and Comparative Example 2.

Specifically, the photoelectrochemical electrode according to the present invention is capable of maintaining high efficiency because the distance-dependent difference in potential inside the photoelectrochemical electrode is constant even when a transition metal dichalcogenide layer having a maximized surface area and a large area is manufactured on the porous substrate, thereby exhibiting high reactivity and reliable performance reproducibility compared to a film-type structure, ultimately improving photoelectrode characteristics and water electrolysis efficiency.

### Test Example 3: Analysis of Photoelectrochemical Electrode

The surfaces of the photoelectrochemical electrodes according to Example 4 and Comparative Example 3 and the carbonized C-fiber textiles, which are porous substrates thereof, were observed, and the results thereof are shown as SEM images.

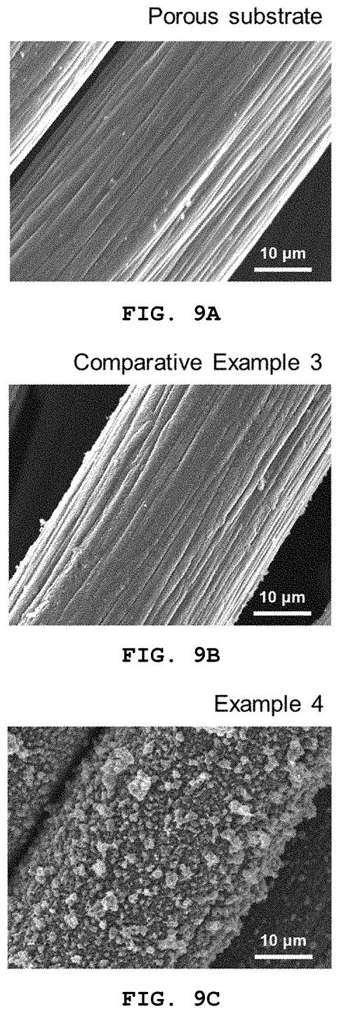

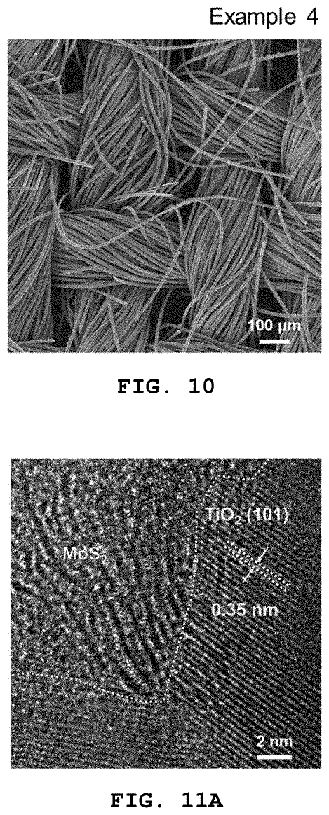

Specifically, FIGS. 9A to 9C are an SEM image of the carbonized C-fiber textile as the porous substrate (FIG. 9A), an SEM image of the photoelectrochemical electrode according to Comparative Example 3 (FIG. 9B), and an SEM image of the photoelectrochemical electrode according to Example 4 (FIG. 9C). Also, FIG. 10 is a low-magnification SEM image of the photoelectrochemical electrode according to Example 4.

With reference to FIGS. 9A to 9C, it can be seen that the surface of the C-fiber textile was smooth, but a rough surface was formed due to the metal oxide layer formed on the surface of the C-fiber textile. Also, it was confirmed that a transition metal dichalcogenide layer having a flower shape in which the transition metal dichalcogenide particles were aggregated was formed on the surface of the metal oxide layer.

Moreover, with reference to FIG. 4, it was confirmed that the photoelectrochemical electrode manufactured using the porous substrate exhibited vastly superior porosity than a typical substrate.

### Test Example 4: Interfacial Analysis in Photoelectrochemical Electrode

The interface between the porous substrate and the metal oxide layer in the photoelectrochemical electrode according to Example 4, and the interface between the metal oxide layer and the transition metal dichalcogenide layer were observed, and the results thereof are shown as TEM images.

FIG. 11A is a TEM image showing the interface between the metal oxide layer and the transition metal dichalcogenide layer in the photoelectrochemical electrode, and FIG. 11B is a TEM image showing the interface between the porous substrate and the metal oxide layer in the photoelectrochemical electrode.

With reference to FIG. 11A, it was confirmed that the TiO₂ layer as the metal oxide layer and the MoS₂ layer as the transition metal dichalcogenide layer were bonded and grown without impurities at the interface therebetween. Also, with reference to FIG. 11B, it was confirmed that the crystalline TiO₂ layer, which is the metal oxide layer, was formed on the amorphous C-fiber textile.

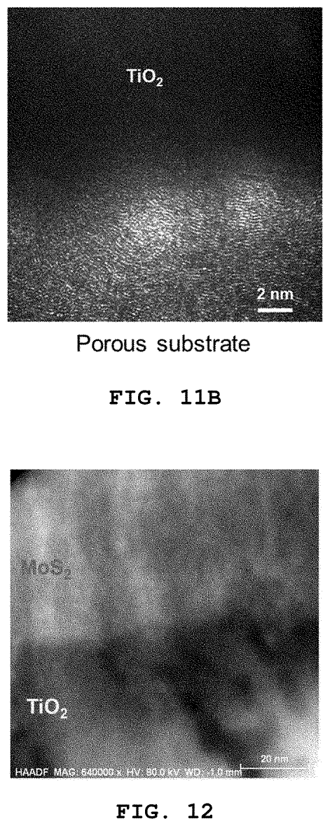

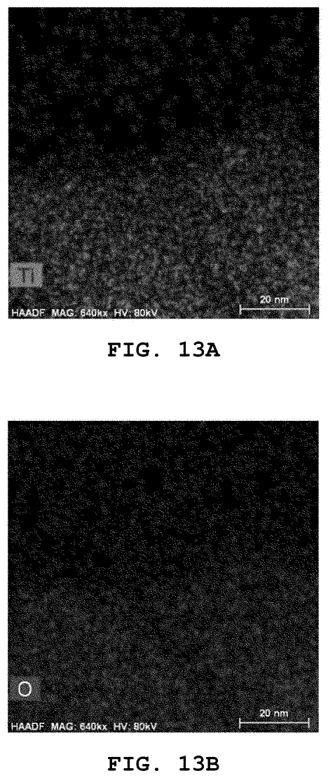

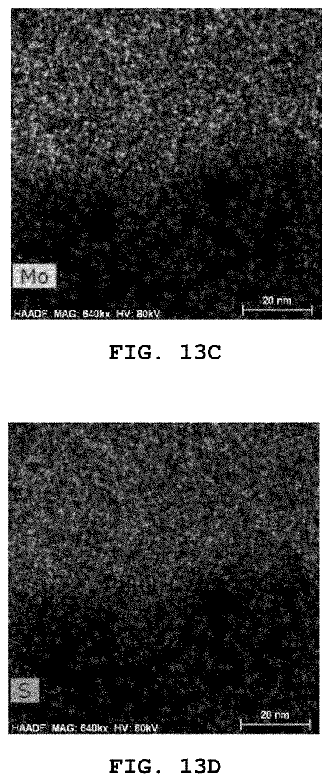

In addition, FIG. 12 is a STEM image showing the interface between the metal oxide layer and the transition metal dichalcogenide layer, and FIGS. 13A to 13D are an image mapped to the Ti element (FIG. 13A), an image mapped to the O element (FIG. 13B), an image mapped to the Mo element (FIG. 13C), and an image mapped to the S element (FIG. 13D), based on the EDX elemental analysis in FIG. 13.

With reference to FIGS. 12 and 13A to 13D, it can be confirmed that the metal oxide layer contains TiO₂ and the transition metal dichalcogenide layer contains MoS₂ through the element disposed in each layer based on each interface.

### Test Example 5: Analysis of Electrical Properties of Photoelectrochemical Electrode

The current density and hydrogen evolution of the photoelectrochemical electrodes according to Example 4, Comparative Example 3, and Comparative Example 4 were measured. In order to confirm a PEC reaction using the reference electrode Ag/AgCl (NaCl 3M) and the counter Pt electrode in a 0.5 M Na₂SO₄ aqueous solution, the current density was analyzed in the voltage range of 0 V to 1.5 V and the hydrogen evolution was analyzed by setting a fixed voltage of 1.23 V (E vs. RHE) and measuring the amount of dissolved hydrogen (μmol/L) over time using a hydrogen sensor. The results thereof are shown in a current density graph and a hydrogen evolution graph, and the photocatalytic efficiency of the photoelectrochemical electrode according to Example 4 was analyzed, and the results thereof are graphed.

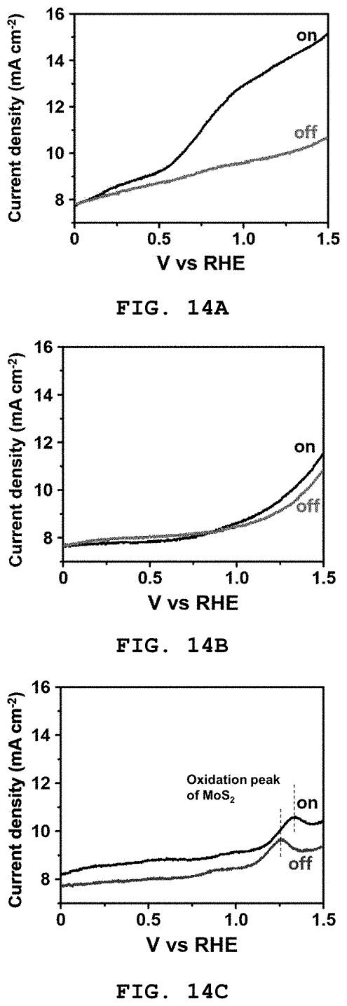

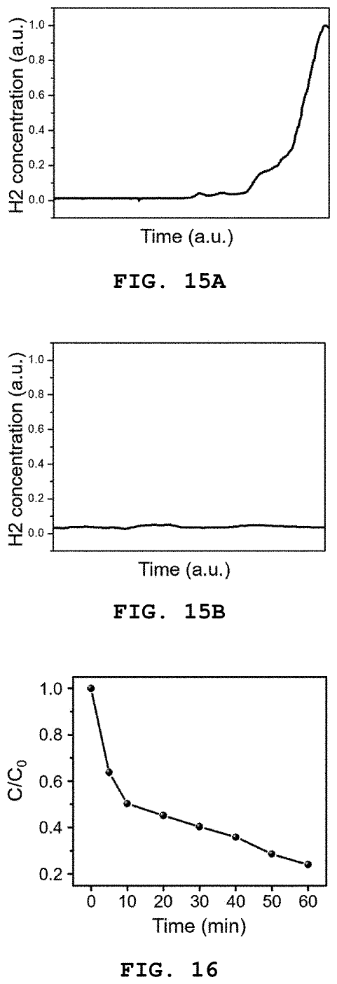

Specifically, FIGS. 14A to 14C are graphs showing the current density results for the photoelectrochemical electrodes according to Example 4 (FIG. 14A), Comparative Example 3 (FIG. 14B), and Comparative Example 4 (FIG. 14C), respectively, and FIGS. 15A and 15B are graphs showing the hydrogen evolution results of the photoelectrochemical electrodes according to Example 4 (FIG. 15A) and Comparative Example 3 (FIG. 15B), respectively. FIG. 16 is a graph showing the photocatalytic efficiency of the photoelectrochemical electrode according to Example 4.

In the current density graph, the larger the on/off gap, the more light the photosensitive material absorbs, thereby generating higher current density, indicating high-efficiency photoelectrochemical properties.

With reference to FIGS. 14A and 14B, the current density gap of the photoelectrochemical electrode according to Example 4 was greater than the current density gap of the photoelectrochemical electrode according to Comparative Example 3, so the current density values were determined to be 13.94 mA/cm² (Example 4) and 9.87 mA/cm² (Comparative Example 3), indicating that the photoelectrochemical electrode according to Example 4 had the highest current density. Moreover, with reference to FIGS. 14A and 14C, the current density value according to Comparative Example 4 was determined to be 0.74 mA/cm², indicating that the current density of the photoelectrochemical electrode manufactured using the porous substrate according to Example 4 was higher than the current density of the photoelectrochemical electrode manufactured using the FTO/glass substrate according to Comparative Example 4. With reference to FIGS. 15A and 15B, the hydrogen evolution rate was increased in proportion to the current density gap, so the light/hydrogen conversion efficiency (η_{STH}) value was calculated using Equation 1 below.

$$η ( \% ) = \frac{{H}_{2} evolution rate \times Δ G}{total incident solar energy \times Area ( {cm}^{2} )} \qquad [ Equation 1 ]$$

The above values were calculated to be 17.15% (Example 4), 12.14% (Comparative Example 3), and 0.15% (Comparative Example 4). The hydrogen evolution rate of the photoelectrochemical electrode according to Example 4 was also determined to be the highest. Moreover, with reference to FIG. 16, it was confirmed that the photocatalytic efficiency of the photoelectrochemical electrode according to Example 4 was excellent.

Specifically, the photoelectrochemical electrode according to the present invention has high reactivity compared to a film-type structure due to the metal oxide layer and the transition metal dichalcogenide layer having a maximized surface area synthesized on the porous substrate and the bonding energy therebetween, thereby improving photoelectrode characteristics and photocatalytic efficiency.

1. A method of manufacturing a photoelectrochemical electrode, comprising:
preparing a porous substrate; and
forming a metal dichalcogenide layer on all or part of a surface of the porous substrate.

2. The method of claim 1, wherein the porous substrate is a carbon fiber textile (C-fiber textile).

3. The method of claim 1, further comprising performing carbonization by heat treatment at a temperature of 950° C. to 1050° C. for 30 minutes to 90 minutes, after preparing the porous substrate.

4. The method of claim 1, wherein the forming the metal dichalcogenide layer comprises:
preparing a growth solution comprising metal dichalcogenide particles;
mixing and dispersing the growth solution and the porous substrate; and
heating a result of dispersion at a temperature of 240° C. to 260° C. for 4 hours to 6 hours.

5. The method of claim 4, wherein the metal dichalcogenide particles comprise:
a metal comprising at least one selected from among molybdenum (Mo), tungsten (W), tin (Sn), niobium (Nb), tantalum (Ta), hafnium (Hf), titanium (Ti), and rhenium (Re); and
a chalcogen element comprising at least one selected from among sulfur (S), selenium (Se), and tellurium (Te).

6. The method of claim 1, further comprising forming a metal oxide layer on all or part of the surface of the porous substrate.

7. The method of claim 6, wherein the forming the metal oxide layer comprises coating the porous substrate with metal oxide nanoparticles using a sputtering system.

8. The method of claim 6, wherein the metal oxide nanoparticles comprise at least one selected from the group consisting of titanium (Ti) oxide, tin (Sn) oxide, indium (In) oxide, magnesium (Mg) oxide, magnesium zinc (MgZn) oxide, indium zinc (InZn) oxide, copper aluminum (CuAl) oxide, silver (Ag) oxide, gallium (Ga) oxide, zinc tin oxide (ZnSnO), zinc indium tin (ZIS) oxide, nickel (Ni) oxide, rhodium (Rh) oxide, ruthenium (Ru) oxide, iridium (Ir) oxide, copper (Cu) oxide, cobalt (Co) oxide, tungsten (W) oxide, zirconium (Zr) oxide, strontium (Sr) oxide, lanthanum (La) oxide, vanadium (V) oxide, molybdenum (Mo) oxide, niobium (Nb) oxide, aluminum (Al) oxide, yttrium (Y) oxide, scandium (Sc) oxide, samarium (Sm) oxide, strontium titanium (SrTi) oxide, and vanadium oxide (V).

9. The method of claim 6, wherein the forming the metal oxide layer is performed at a pressure of 0.5 mTorr or more in an atmosphere containing an inert gas.

10. A photoelectrochemical electrode, comprising:
a porous substrate; and
a metal dichalcogenide layer located on all or part of a surface of the porous substrate.

11. The photoelectrochemical electrode of claim 10, wherein the porous substrate is a carbon fiber textile (C-fiber textile).

12. The photoelectrochemical electrode of claim 10, wherein the metal dichalcogenide layer has a flower or sea urchin shape in which metal dichalcogenide particles are aggregated, and a thin-film shape.

13. The photoelectrochemical electrode of claim 12, wherein the metal dichalcogenide particles comprise:
a metal comprising at least one selected from among molybdenum (Mo), tungsten (W), tin (Sn), niobium (Nb), tantalum (Ta), hafnium (Hf), titanium (Ti), and rhenium (Re); and
a chalcogen element comprising at least one selected from among sulfur (S), selenium (Se), and tellurium (Te).

14. The photoelectrochemical electrode of claim 10, further comprising a metal oxide layer located on all or part of the surface of the porous substrate.

15. The photoelectrochemical electrode of claim 14, wherein metal oxide nanoparticles in the metal oxide layer comprise at least one selected from the group consisting of titanium (Ti) oxide, tin (Sn) oxide, indium (In) oxide, magnesium (Mg) oxide, magnesium zinc (MgZn) oxide, indium zinc (InZn) oxide, copper aluminum (CuAl) oxide, silver (Ag) oxide, gallium (Ga) oxide, zinc tin oxide (ZnSnO), zinc indium tin (ZIS) oxide, nickel (Ni) oxide, rhodium (Rh) oxide, ruthenium (Ru) oxide, iridium (Ir) oxide, copper (Cu) oxide, cobalt (Co) oxide, tungsten (W) oxide, zirconium (Zr) oxide, strontium (Sr) oxide, lanthanum (La) oxide, vanadium (V) oxide, molybdenum (Mo) oxide, niobium (Nb) oxide, aluminum (Al) oxide, yttrium (Y) oxide, scandium (Sc) oxide, samarium (Sm) oxide, strontium titanium (SrTi) oxide, and vanadium oxide (V).

16. The photoelectrochemical electrode of claim 14, wherein a thickness of the metal oxide layer is 300 nm to 1 μm.
